(19) United States
(12) Patent Application Publication
(10) Pub. No.: US 2003/0006492 A1
(43) Pub. Date: Jan. 9, 2003

(54) Semiconductor device and method of manufacturing the same

(76) Inventors: Kazuto Ogasawara, Hakodate (JP); Mitsugu Tanaka, Hakodate (JP); Seiichi Tomihara, Nanae (JP)

Correspondence Address: Mattingly, Stanger & Malur, P.C., Suite 370, 1800 Diagonal Road, Alexandria, VA, 22314, US

(21) Appl. No.: 10/157,823

(22) Filed: May 31, 2002

(30) Foreign Application Priority Data
Jul. 9, 2001 (JP) 2001-207701

(51) Int. Cl. H01L 23/495; H01L 23/06; H01L 23/48; H01L 23/52; H01L 29/40; H01L 23/28; H01L 23/29

(52) U.S. Cl. 257/684; 257/796; 257/666; 257/676; 257/675; 257/788; 257/692; 257/696; 257/784; 257/786

(57) ABSTRACT

A semiconductor device includes a resin sealing portion which has a plurality of side surfaces and a back surface which is formed between the side surfaces, a semiconductor chip which has a plurality of pads on a main surface thereof, a plurality of leads which are formed of conductor and each of which has a bonding portion, an external connection terminal portion and a cut portion, a plurality of wires which connect a plurality of leads and a plurality of pads of the semiconductor chip to each other, and a tab on which the semiconductor chip is mounted. By making the thickness of the cut portion of the lead smaller than the thickness of the external connection terminal portion, a lead sagging which is generated on the side surfaces of the resin sealing portion when the lead is cut by dicing after molding can be reduced.

### BACKGROUND OF THE INVENTION

The present invention relates to a semiconductor manufacturing technique, and more particularly to an effective technique suitable for the enhancement of the reliability of a semiconductor device.

Among resin-sealed semiconductor devices which aim at miniaturizing thereof, in a semiconductor device which is assembled using a lead frame, there has been proposed a method in which semiconductor chips are mounted on respective tabs (chip mounting portions) of the lead frame for producing a large number of semiconductor devices and, thereafter, molding is performed by covering a plurality of device regions in the lead frame with one cavity of a mold frame (hereinafter, the molding method being referred to as “block” molding method).

In such a semiconductor device, after performing the block molding, the mold is individually divided by dicing.

Here, a method for manufacturing a resin-sealed or resin-encapsulated semiconductor device which is assembled by the block molding method using the lead frame is described in Japanese Unexamined Patent Publication No. 2001-24001, for example. Here disclosed is a technique in which by performing a resin mold up to opening portions formed in a peripheral portion of a device region of a lead frame, an inner stress of a molded product which is generated in a cutting step is decreased so that the warpage of the molded product is reduced whereby the productivity and the quality are enhanced.

### SUMMARY OF THE INVENTION

However, as explained in conjunction with the above-mentioned technique, in assembling the semiconductor device by the block molding using the lead frame, after performing the molding, it is necessary to cut the resin sealing portion and the lead of the lead frame altogether and hence, a package which is a mixture of the metal lead and the resin sealing portion is cut by a dicing blade or the like.

By performing the cutting using such a dicing blade, there arises a phenomenon referred to as “lead sagging” (lead sagging 11 shown in a comparison example of FIG. 34) in which metal which constitutes a lead is adhered to an outer periphery of a cut surface of the lead due to a friction generated at the time of cutting (dicing stress). When the lead sagging 11 is projected from a lead mounting surface, the flatness of the lead mounting surface is deteriorated so that there arises a problem that the substrate adhesive strength is lowered and, at the same time, the substrate mounting ability becomes unstable.

Further, there arises a problem that a short-circuiting between leads is generated due to the adhered lead sagging.

Particularly, when a solder plating film is formed on the lead mounting surface, the solder plating film is more liable to form the sagging than the lead and hence, the above-mentioned problem is more liable to be generated.

Incidentally, in Japanese Unexamined Patent Publication No. 2001-24001, there is no description of the lead sagging which is generated when the lead is cut.

Accordingly, it is an object of the present invention to provide a semiconductor device and a manufacturing method thereof which can enhance the reliability by preventing the projection of a lead sagging toward a mounting surface of a lead.

It is another object of the present invention to provide a semiconductor device and a manufacturing method thereof which can enhance the reliability by preventing a short-circuiting between leads.

It is still another object of the present invention to provide a semiconductor device and a manufacturing method thereof which can enhance the substrate connection strength.

It is a further object of the present invention to provide a method for manufacturing a semiconductor device which can prevent the generation of resin flash on a lead mounting surface.

The above-mentioned object, other object and novel features of the present invention will be apparent from the description of this specification and attached drawings.

To briefly explain the summary of typical inventions out of inventions disclosed in the present specification, they are as follows.

That is, the present invention is directed to a semiconductor device including a resin sealing portion which has a mounting surface formed between a plurality of side surfaces, a semiconductor chip which is sealed by the resin sealing portion, a plurality of leads each of which respectively has a first portion thereof sealed by the resin sealing portion, a second portion thereof exposed to the mounting surface and third portions thereof exposed to the side surfaces and being formed of conductor, wherein the semiconductor device further includes a plurality of wires which electrically connect the plurality of leads and a plurality of electrodes of the semiconductor chip, and a plating film is formed on surfaces of the second portions of the leads, and the plating film is not formed on surfaces of the third portions of the lead.

Further, a manufacturing method of a semiconductor according to the present invention includes a step of preparing a lead frame having a first frame portion, a second frame portion which is formed in the inside of the first frame portion, a plurality of device regions which are formed in the inside of the second frame portion, a plurality of electrode portions which are respectively formed on the plurality of device regions, and first films which are laminated to a plurality of electrode portions, a step of fixedly mounting semiconductor chips on the device regions of the lead frame, a step of respectively connecting electrodes of the semiconductor chips and the electrode portions of the lead frame to each other by means of wires, a step of sealing the plurality of semiconductor chips, the plurality of wires and a portion of the lead frame with sealing resin, a step of removing the first films which are laminated to the electrode portions after the sealing step and at least portion of the plurality of electrode portions is exposed, and a step of separating the lead frame and the sealing resin portion corresponding to respective device regions after the sealing step.

### BRIEF DESCRIPTION OF THE DRAWINGS

FIG. 1 is a cross-sectional view showing one example of the structure of a semiconductor device (QFN) of the embodiment 1 of the present invention.

FIG. 2 is a side view showing the structure of the semiconductor device shown in FIG. 1.

FIG. 3 is a bottom plan view showing the structure of the semiconductor device shown in FIG. 1.

FIG. 4 is a plan view showing one example of the structure of a lead frame which is used for assembling the semiconductor device shown in FIG. 1.

FIG. 5 is a cross-sectional view showing one example of the structure of the lead frame shown in FIG. 4 after a tape is laminated to the lead frame.

FIG. 6 is a cross-sectional view showing one example of the structure in a semiconductor chip fixed state in the assembling of the semiconductor device shown in FIG. 1.

FIG. 7 is a cross-sectional view showing one example of the structure in a wire bonding state in the assembling of the semiconductor device shown in FIG. 1.

FIG. 8 is a cross-sectional view showing one example of the structure after molding in the assembling of the semiconductor device shown in FIG. 1.

FIG. 9 is a cross-sectional view showing one example of the structure in a tape-peeled-off state in the assembling of the semiconductor device shown in FIG. 1.

FIG. 10 is a cross-sectional view showing one example of the structure in an exterior plated state in the assembling of the semiconductor device shown in FIG. 1.

FIG. 11 is a cross-sectional view showing one example of the structure in a dicing state in the assembling of the semiconductor device shown in FIG. 1.

FIG. 12 is a cross-sectional view showing one example of the structure after dicing in the assembling of the semiconductor device shown in FIG. 1.

FIG. 13 is a cross-sectional view showing one example of the structure of the lead frame in the assembling of the semiconductor device shown in FIG. 1.

FIG. 14 is an enlarged partial cross-sectional view showing the structure of a portion A shown in FIG. 13.

FIG. 15 is an enlarged partial side view showing one example of a lead sagging state of the semiconductor device which is assembled using the lead frame shown in FIG. 13.

FIG. 16 is a bottom plan view showing one example of the structure of the lead frame after block molding in the assembling of the semiconductor device shown in FIG. 1.

FIG. 17 is plan view showing one example of the structure of the lead frame after block molding in the assembling of the semiconductor device shown in FIG. 1.

FIG. 18 is a partial bottom plan view showing the structure after block molding in the assembling using a lead frame of a modification of the embodiment 1 of the present invention.

FIG. 19 is an enlarged partial bottom plan view showing the structure of a portion B shown in FIG. 18.

FIG. 20 is an enlarged partial side view showing a lead sagging state of a semiconductor device which is assembled using a lead frame of a modification shown in FIG. 19.

FIG. 21 is a cross-sectional view showing one example of the structure of a semiconductor device (QFN) of the second embodiment of the present invention.

FIG. 22 is a side view showing the structure of the semiconductor device shown in FIG. 21.

FIG. 23 is a bottom plan view showing the structure of the semiconductor device shown in FIG. 21.

FIG. 24 is a plan view showing one example of the structure of a lead frame used in the assembling of the semiconductor device shown in FIG. 21.

FIG. 25 is a cross-sectional view showing one example of the structure after a tape is laminated to the lead frame shown in FIG. 24.

FIG. 26 is a cross-sectional view showing one example of a structure in a semiconductor chip fixed state in the assembling of the semiconductor device shown in FIG. 21.

FIG. 27 is a cross-sectional view showing one example of a semiconductor wafer structure for obtaining semiconductor chips in a fixed state in the assembling of the semiconductor device shown in FIG. 21.

FIG. 28 is a cross-sectional view showing one example in a dicing state in the assembling of a semiconductor device of another embodiment of the present invention.

FIG. 29 is a cross-sectional view showing one example in a post-dicing state in the assembling of a semiconductor device of another embodiment of the present invention.

FIG. 30 is an enlarged partial plan view showing the structure of a lead frame used in the assembling of the semiconductor device of another embodiment of the present invention.

FIG. 31 is a partial cross-sectional view showing the structure of a cut portion of the lead frame used in the assembling of the semiconductor device of another embodiment of the present invention.

FIG. 32 is a partial cross-sectional view showing the structure of a cut portion of the lead frame used in the assembling of the semiconductor device of another embodiment of the present invention.

FIG. 33 is a side view showing one example of the structure of a semiconductor device of a comparison example which is provided for comparison with the semiconductor device of the present invention.

FIG. 34 is an enlarged partial side view showing a lead sagging state at a portion C of the semiconductor device of the comparison example shown in FIG. 33.

FIG. 35 is a cross-sectional view showing one example of the structure in a state that the semiconductor device shown in FIG. 21 is mounted on a mounting substrate.

### DETAILED DESCRIPTION OF THE PREFERRED EMBODIMENTS

Preferred embodiments of the present invention are explained hereinafter in conjunction with attached drawings. In all drawings served for explaining the embodiments, parts which have identical functions are indicated by same symbols and the repeated explanation of the parts are omitted.

(Embodiment 1)

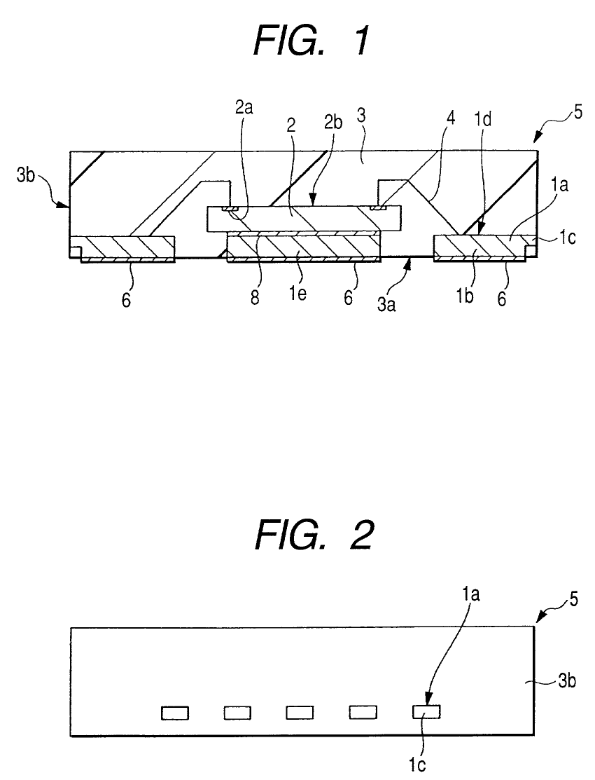

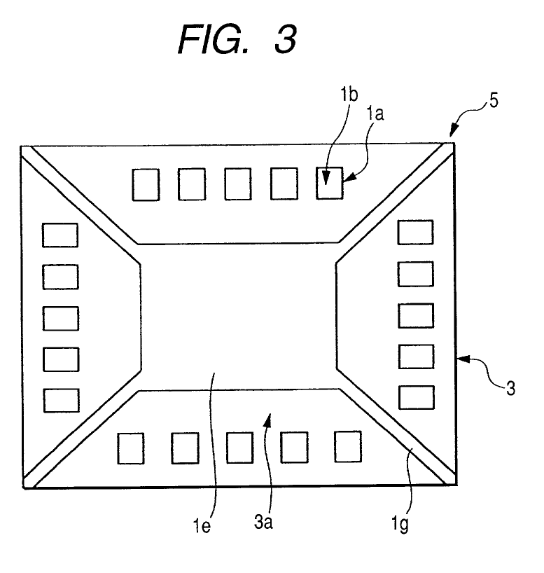

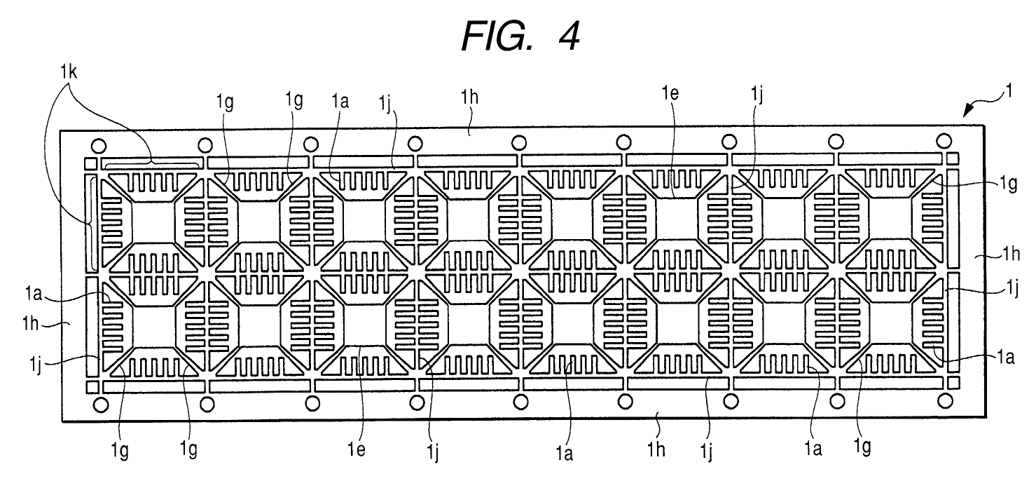

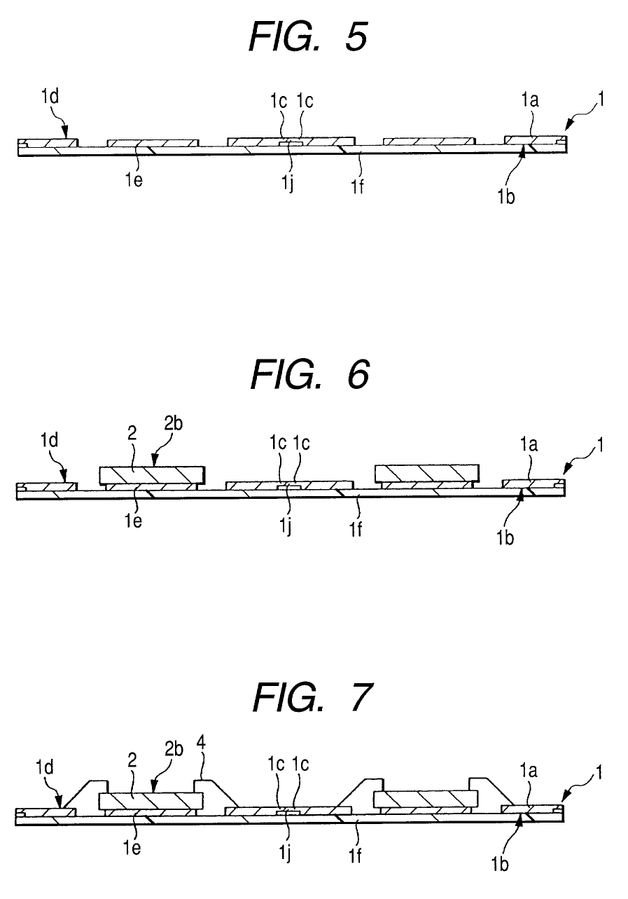

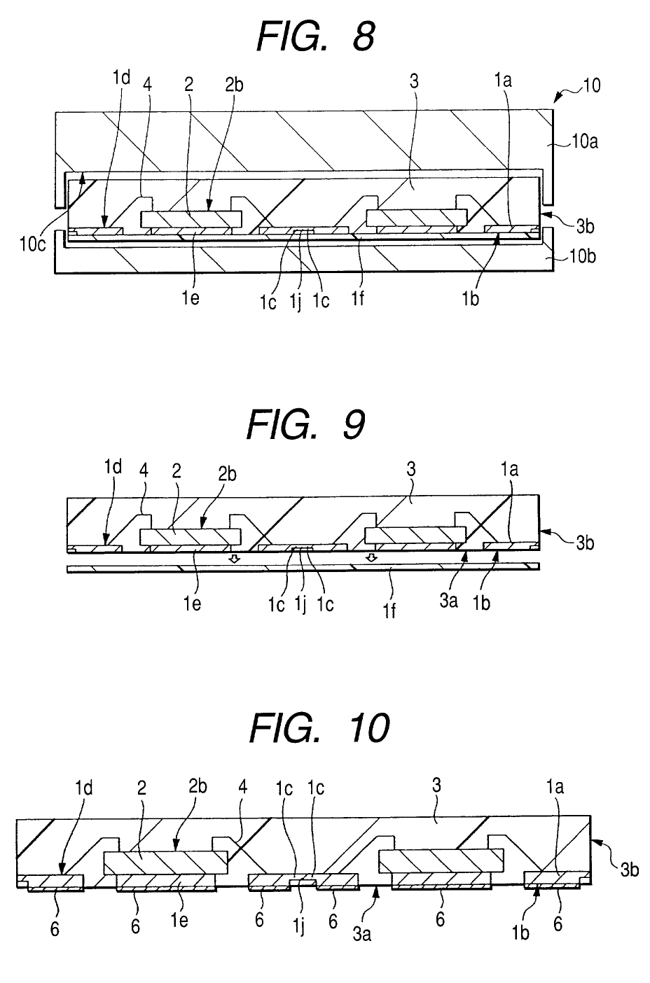

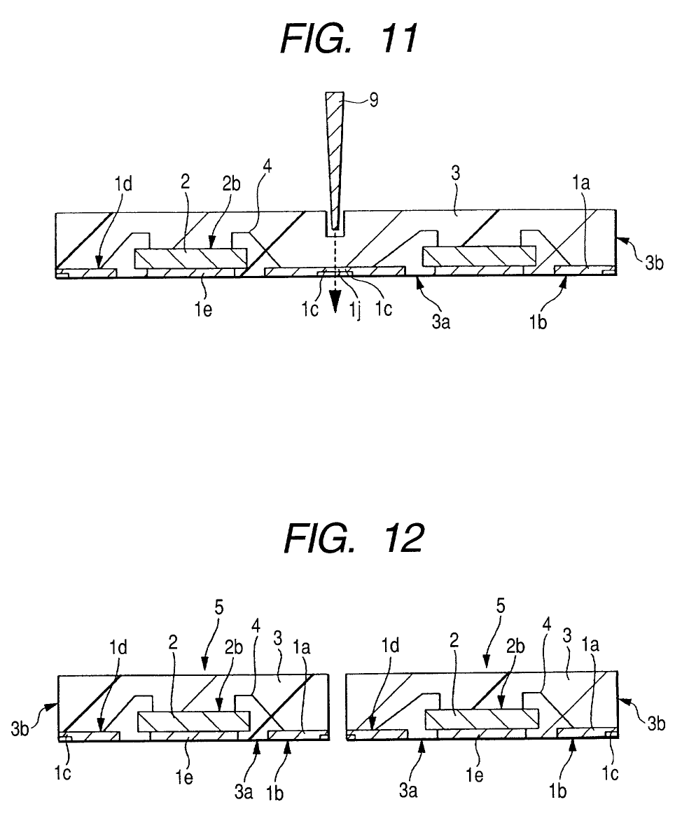

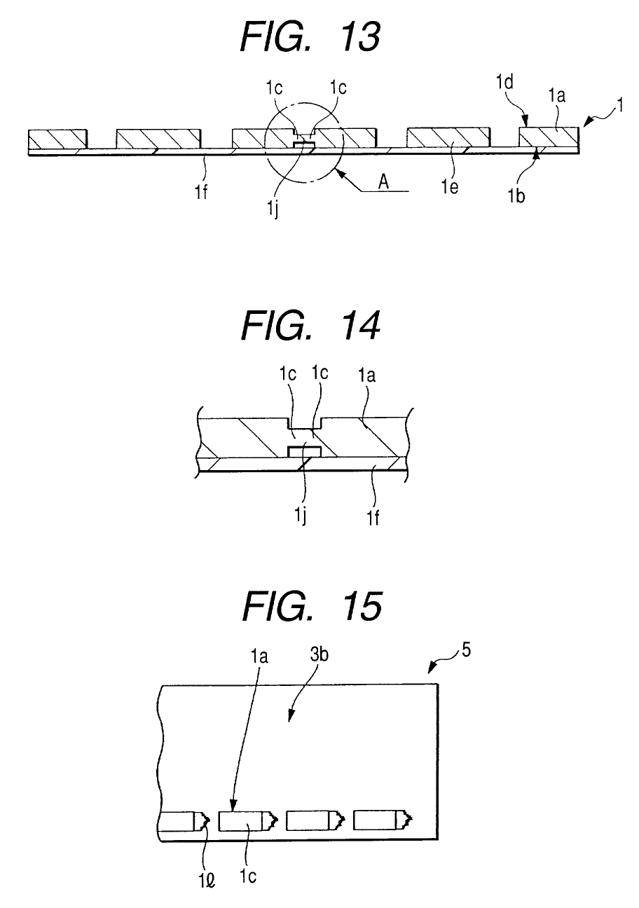

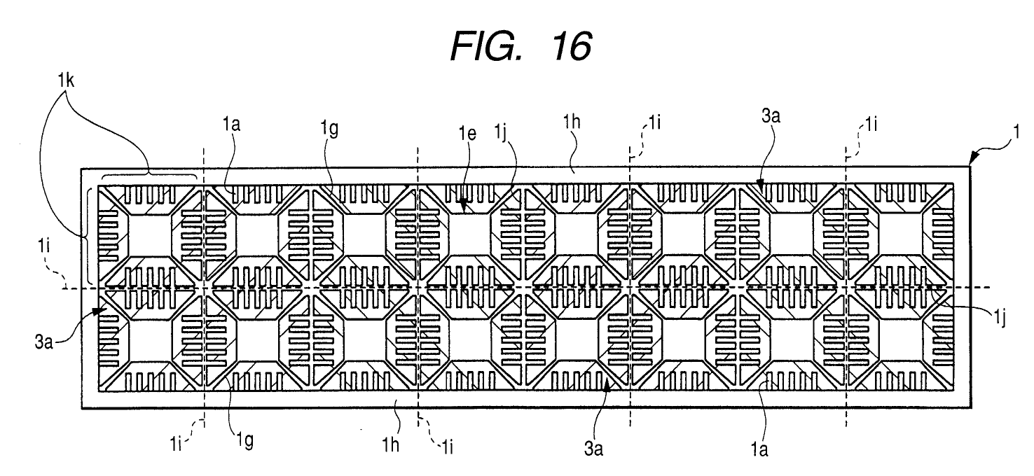

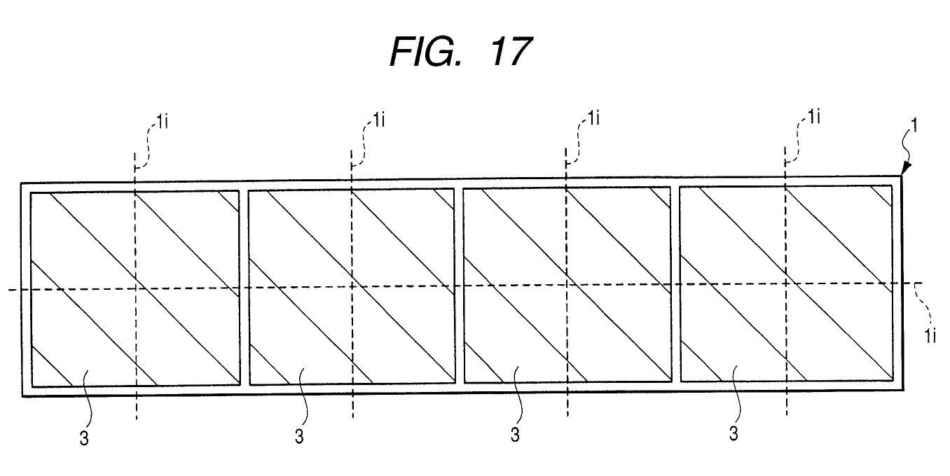

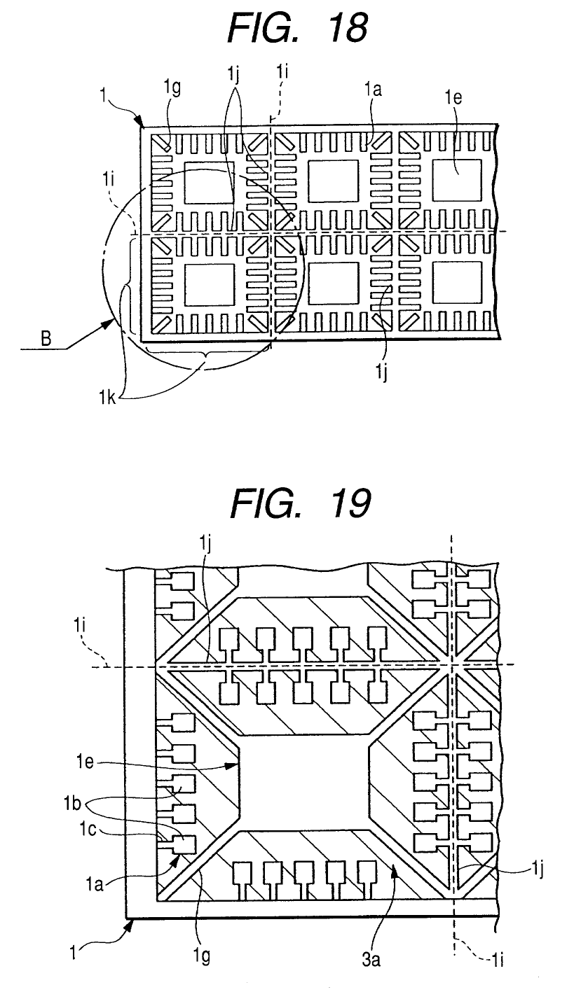

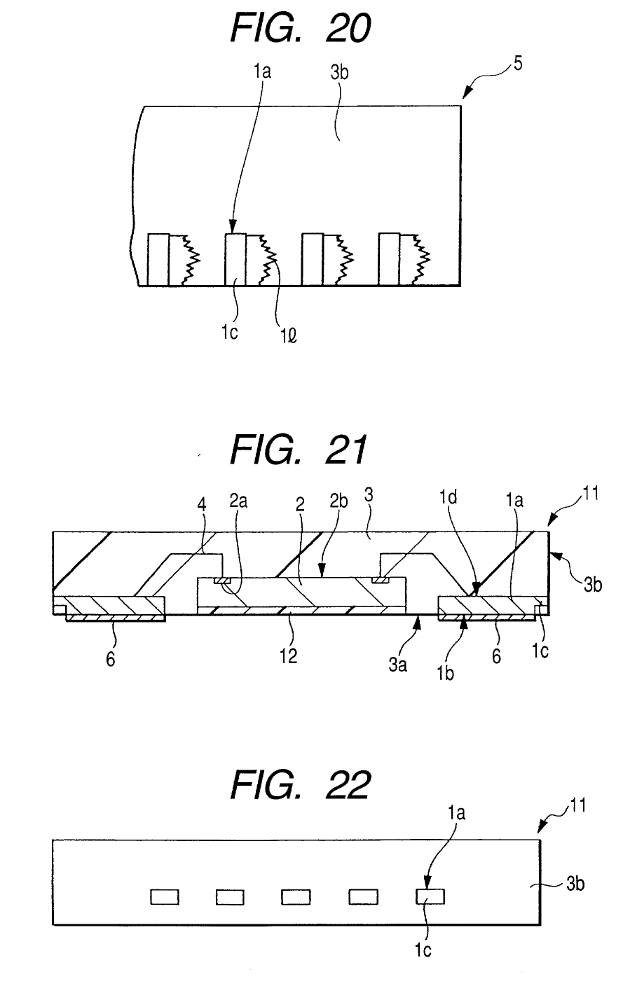

In the drawings, FIG. 1 is a cross-sectional view showing one example of the structure of a semiconductor device (QFN) of the embodiment 1 of the present invention, FIG. 2 is a side view showing the structure of the semiconductor device shown in FIG. 1, FIG. 3 is a bottom plan view showing the structure of the semiconductor device shown in FIG. 1, FIG. 4 is a plan view showing one example of the structure of a lead frame which is used for assembling the semiconductor device shown in FIG. 1, FIG. 5 is a cross-sectional view showing one example of the structure of the lead frame shown in FIG. 4 after a tape is laminated to the lead frame, FIG. 6 is a cross-sectional view showing one example of the structure in a semiconductor chip fixed state in the assembling of the semiconductor device shown in FIG. 1, FIG. 7 is a cross-sectional view showing one example of the structure in a wire bonding state in the assembling of the semiconductor device shown in FIG. 1, FIG. 8 is a cross-sectional view showing one example of the structure after molding in the assembling of the semiconductor device shown in FIG. 1, FIG. 9 is a cross-sectional view showing one example of the structure in a tape-peeled-off state in the assembling of the semiconductor device shown in FIG. 1, FIG. 10 is a cross-sectional view showing one example of the structure in an exterior plated state in the assembling of the semiconductor device shown in FIG. 1, FIG. 11 is a cross-sectional view showing one example of the structure in a dicing state in the assembling of the semiconductor device shown in FIG. 1, FIG. 12 is a cross-sectional view showing one example of the structure after dicing in the assembling of the semiconductor device shown in FIG. 1, FIG. 13 is a cross-sectional view showing one example of the structure of the lead frame in the assembling of the semiconductor device shown in FIG. 1, FIG. 14 is an enlarged partial cross-sectional view showing the structure of a portion A shown in FIG. 13, FIG. 15 is an enlarged partial side view showing one example of a lead sagging state of the semiconductor device which is assembled using the lead frame shown in FIG. 13, FIG. 16 is a bottom plan view showing one example of the structure after block molding in the assembling of the semiconductor device shown in FIG. 1, FIG. 17 is plan view showing one example of the structure after block molding in the assembling of the semiconductor device shown in FIG. 1, FIG. 18 is a partial bottom plan view showing the structure after block molding in the assembling using a lead frame of a modification of the embodiment 1 of the present invention, FIG. 19 is an enlarged partial bottom plan view showing the structure of a portion B shown in FIG. 18, and FIG. 20 is an enlarged partial side view showing a lead sagging state of a semiconductor device which is assembled using a lead frame of a modification shown in FIG. 19.

The semiconductor device shown in FIG. 1 to FIG. 3 is a small-sized semiconductor package of a resin sealing type as well as of a surface mounting type. In this embodiment 1, a QFN (Quad Flat Non-leaded Package) 5 is explained as one example of the semiconductor device.

As shown in FIG. 3, the QFN 5 is the semiconductor device of a peripheral type. In the QFN 5, the external connection terminal portions (second portions) 1b of a plurality of leads (electrode portions) 1a shown in FIG. 1 have surfaces (exposed surfaces) thereof arranged in an exposed manner in parallel along a peripheral portion of a mounting surface (hereinafter referred to as “back surface 3a” ) of a resin sealing portion 3 formed of a resin mold. Each lead 1a performs a function of an inner lead which is embedded into the resin sealing portion 3 as well as a function of an outer lead which is exposed on the back surface 3a of the resin sealing portion 3. Each lead 1a includes a bonding portion 1d which is sealed by the resin sealing portion 3 and constitutes a first portion to which wires 4 are connected, an external connection terminal portion 1b which is provided with a surface exposed to the back surface 3a of the resin sealing portion 3 and constitutes a second portion, and a cut portion 1c which is provided with a surface exposed to a side surface 3b of the resin sealing portion 3 and constitutes a third portion.

Further, the QFN 5 is a semiconductor device which is produced as follows. That is, using a multi-cavity lead frame 1 shown in FIG. 4, a block molding is performed such that a plurality of device regions 1k in the lead frame 1 are molded by covering the device regions 1k with one cavity 10c of a mold frame 10 shown in FIG. 8. Thereafter, the device regions are divided and assembled as individual QFNs 5.

Subsequently, to explain the detailed constitution of the QFN 5, the QFN 5 includes the resin sealing portion 3 which has a plurality of sides 3b and a back surface 3a which is formed between the plurality of side surfaces 3b and constitutes a mounting surface, the semiconductor chip 2 which has a pad 2a constituting a plurality of electrodes on a main surface 2b and is sealed with the resin sealing portion 3, a plurality of leads 1a which are formed of conductor and each of which has the bonding portion 1d, the external connection terminal portion 1b and the cut portion 1c, a plurality of wires 4 which are sealed with the resin sealing portion 3 and respectively electrically connect the plurality of leads 1a and the plurality of pads 2a of the semiconductor chip 2, and a tab 1le which constitutes a chip mounting portion on which the semiconductor chip 2 is mounted. As shown in FIG. 1, on surfaces of the external connection terminal portions 1b which constitute the second portions of the lead 1a and are exposed to the back surface 3a of the resin sealing portion 3, a plating film 6 is formed by soldering, while on surfaces of the cut portions 1c of the lead 1a which constitute the third portions, the plating film 6 is not formed.

That is, according to the embodiment 1, as shown in FIG. 13 and FIG. 14, the thickness of the cut portion 1c of the lead 1a of the lead frame 1 shown in FIG. 4 which is used for assembling the QFN 5 is made smaller than the thickness of the external connection terminal portion 1b and the cut portion 1c is used as a dicing area after molding to perform dicing. Accordingly, the generation of lead sagging (lead burring) 11 shown in FIG. 15 which is formed on the side surfaces 3b of the resin sealing portion 3 at the time of cutting the lead by dicing can be largely reduced compared to a lead sagging 11 of the comparison example shown in FIG. 34.

To reduce the lead sagging 11, it is preferable to make the cross-sectional area of the cut portion 1c on a plane which is parallel to the side surfaces 3b of the resin sealing portion 3 where the cut portions 1c of the lead 1a are exposed smaller than the cross-sectional area of the external connection terminal portions 1b. In the QFN 5 of the embodiment 1 shown in FIG. 1 to FIG. 3, an example in which the thickness of the cut portions 1c of the lead 1a is made smaller than the thickness of the external connection terminal portion 1b is shown.

Here, the lead sagging 11 is generated due to a phenomenon that when a composite body formed of the metal-made lead 1a and the resin-made resin sealing portion 3 is cut using a rasp-shaped machining member such as a dicing blade 9 shown in FIG. 11, metal which constitutes the lead 1a is adhered or stuck to an end surface of the lead 1a due to a friction generated. This phenomenon appears remarkably when copper or a copper alloy exhibiting low hardness is used as the material of lead 1a.

However, even when the copper or the copper alloy is used as the material of the lead 1a, by setting the cross-sectional area of the cut portion 1c of the lead 1a in the direction parallel to the side surface 3b smaller than the cross-sectional area of the external connection terminal portion 1b, an absolute quantity of adhered metal generated by the phenomenon can be reduced so that the short-circuiting of the leads can be prevented.

Here, when the thickness of the cut portion 1c of the lead 1a is made smaller than the thickness of the external connection terminal portion 1b so as to reduce the cross-sectional area, the cut portion 1c is covered with the resin at the time of sealing as shown in FIG. 1 so that the cut portion 1c is embedded in the inside of the resin sealing portion 3 whereby the cut portion 1c is not exposed to the back surface 3a of the resin sealing portion 3.

Accordingly, even when the plating film 6 is formed by performing solder plating by using material which exhibits hardness lower than that of the copper or the copper alloy on the surface (exposed surface) of the external connection terminal 1b of the lead 1a which is exposed to the back surface 3a of the resin sealing portion 3 after resin sealing, the solder plating is not formed on the surface of the cut portion 1c. Accordingly, by dicing the lead 1a and an inner frame portion 1j which constitute portions applied with no solder plating, the generation of sagging due to the solder plating which exhibits hardness lower than that of sagging of lead 1a and hence is easily liable to generate the sagging can be prevented and the short-circuiting between the cut portions 1c of the lead 1a due to the lead sagging 11 can be prevented.

Further, as shown in FIG. 15, it is possible to prevent the projection of the lead sagging 11 to the back surface 3a of the resin sealing portion 3 so that the deterioration of the substrate connection strength can be prevented whereby the reliability of the QFN 5 can be enhanced and, at the same time, the yield rate can be enhanced.

With respect to machining for making the thickness of the cut portion 1c of the lead 1a thinner than the thickness of the external connection terminal portion 1b, half etching machining or press machining such as coining can be used. Further, both of half etching and coining may be used.

Further, since it is possible to prevent the projection of the lead sagging 11 to the back surface 3a of the resin sealing portion 3, the flatness of the exposed surface of the external connection terminal portion 1b to the back surface 3a of the resin sealing portion 3 can be ensured whereby the solder wettability at the time of mounting the QFN 5 to the substrate can be ensured.

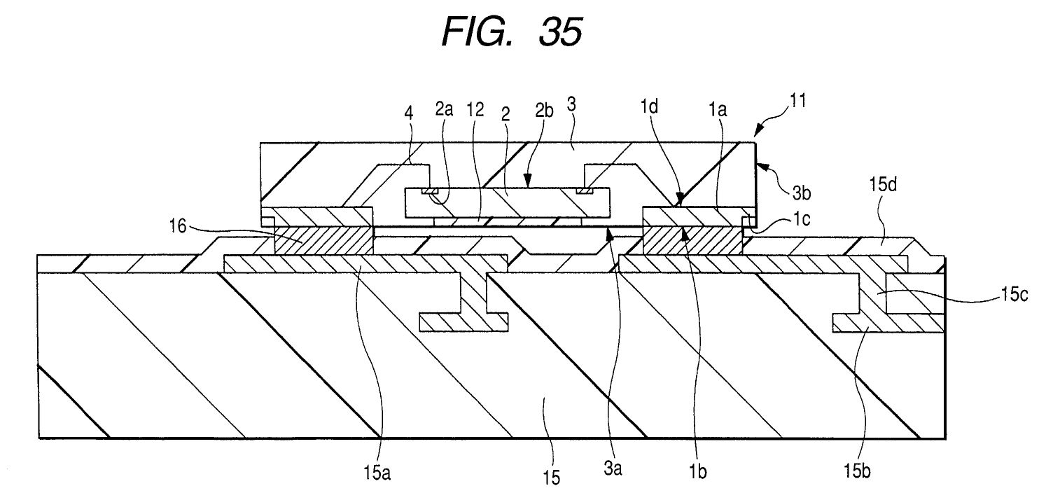

Accordingly, the substrate connection strength of the QFN 5 when the QFN 5 is mounted on the mounting substrate 15 (see FIG. 35) can be enhanced.

Further, by making the thickness of the cut portion 1c of the lead 1a smaller than the thickness of the external connection terminal portion 1b, a stress applied to the cutting surface when the lead is cut (or divided into individual QFNs 5) by dicing can be reduced.

Accordingly, the peeling between the lead 1a and the resin sealing portion 3 can be reduced and hence, the reliability of the QFN 5 can be enhanced and the yield rate of the QFN 5 can be enhanced.

Here, with respect to the QFN 5 of the embodiment 1, as shown in FIG. 1, the semiconductor chip 2 is fixed to the tab (chip mounting portion) 1e by way of a die bonding material 8 such as a silver paste, for example.

Further, as shown in FIG. 4, each tab 1e has corner portions thereof supported by suspension leads 1g. That is, the QFN 5 of the embodiment 1, as shown in FIG. 3, adopts the tab exposure structure in which the tabs 1e and the suspension leads 1g are exposed on the back surface 3a of the resin sealing portion 3.

Further, the wires 4 are, for example, made of gold lines and the resin which forms the resin sealing portion 3 is made of thermosetting epoxy resin or the like, for example.

Subsequently, the method for manufacturing the QFN 5 of the embodiment 1 is explained hereinafter.

Here, the QFNs 5 are assembled by adopting a tape molding method such that the block molding is performed and, thereafter, the lead frame 1 is divided into individual QFNs 5 by dicing, and a piece of tape having an adhesive strength is laminated to each lead 1a.

The reason that the tape molding method is adopted is as follows. In performing the block molding using the multi-cavity lead frame 1 shown in FIG. 4, with respect to the lead frame 1 which is arranged in the inside of a cavity 10c of a mold frame 10 shown in FIG. 8, by preventing the floating of the lead 1a which is arranged toward the inside remote from a mold line from the tape, the occurrence of resin flash burrs can be prevented and the external connection terminal portions 1b of the leads 1a can be projected toward the back surface 3a of the resin sealding portion 3.

That is, with respect to the conventional QFNs, to prevent the turn-around (resin flash) of thin seal resin to the electrode mounting surface in a resin sealing step and to ensure the projection of electrodes from the seal resin, a sheet molding method has been adopted. However, compared to the conventional molding method in which respective electrodes are arranged in the vicinity of an outer periphery of the mold line (profile of the cavity 10c), the leads 1a which are arranged at a position disposed inside and far remote from the mold line in the block molding method. Accordingly, in the conventional molding method which presses the leads 1a to the sheet using only the clamping force of the mold frame 10, it is difficult to prevent the occurrence of the resin flash and to allow the leads 1a to be projected from the back surface 3a of the resin sealing portion 3.

In view of the above, the block molding method of the embodiment 1 adopts the tape molding method in which a sheet of tape having the adhesive force is laminated to respective leads 1a.

Further, in adopting the tape molding method, it is preferable to perform a step for laminating the tape for tape molding to the lead frame 1 before a wire bonding step. It is more preferable to perform such a step before a die bonding step.

This is because when the tape is laminated after the wire bonding step, since the semiconductor chips 2 and wires 4 are connected to the lead frame 1, portions at which the leads 1a can be pressed for lamination are substantially restricted only to the dicing regions.

In the lamination step which presses only such narrow regions, it is difficult to ensure the reliability with respect to the adhesion between the leads 1a and the tape and, at the same time, the flatness of the leads 1a is deteriorated. Accordingly, it is preferable to perform the lamination of the tape for tape molding to the lead frame 1 prior to the die bonding step or the wire bonding step.

Further, in adopting the tape molding method, in the embodiment 1, the QFNs 5 have the tab exposure structure shown in FIG. 1 to FIG. 3. The tab exposure structure is explained hereinafter.

The reason that this tab exposure structure is adopted is as follows. That is, in the manufacturing method in which the tape for tape molding is laminated prior to the die bonding step and the wire bonding step, it is necessary to perform the die bonding step and the wire bonding step in the state that the back surfaces of the tabs le are laminated to the tape.

That is, to cover the back surfaces of the tabs 1e with the seal resin, it is necessary to form a gap in which the seal resin flows between the tape and the tabs 1e preliminarily. However, in the above-mentioned manufacturing method in which the tape is preliminarily laminated to the lead frame 1, when the gap is provided between the tabs 1e and the tape, it is impossible to support the tabs 1e from below (from tape side) and hence, it is difficult to ensure the stability and the flatness of the tabs 1e.

In this manner, it is extremely difficult to perform the die bonding and the wire bonding in the state that tabs 1e are unstable.

Further, although heating is performed from a stage on which the lead frame 1 is mounted to conduct a temperature control of the semiconductor chips 2 in the wire bonding step, in the state that the gap is defined between the tabs 1e and the tape, heat from the stage is hardly transmitted to the semiconductor chip 2 and, at the same time, it is difficult to uniformly heat the semiconductor chips 2 so that the temperature control becomes unstable.

To the contrary, by preliminarily laminating the tabs 1e and the tape to each other, while it is possible to ensure the stability of the tabs 1e in the die bonding step and the wire bonding step, it is also possible to perform the temperature control using a stage in a more stable manner in the wire bonding step.

By performing the resin sealing step in the state that the tabs 1e are laminated to the tape in the above-mentioned manner, it is possible to provide the structure which exposes the back surface of the tab 1e to the back surface 3a of the resin sealing portion 3. The QFNs 5 which are assembled in this method are shown in FIG. 1 to FIG. 3.

Subsequently, the specific manufacturing steps of the QFNs 5 shown in FIG. 1 to FIG. 3 are explained. First of all, the lead frame 1 is prepared, wherein the lead frame 1 includes an outer frame portion 1h which constitutes a first frame portion, an inner frame portion 1j which is formed inside the outer frame portion 1h and constitutes a second frame portion, a plurality of device regions 1k which are formed inside the inner frame portion 1j, the leads 1a which are respectively formed in the plurality of device regions 1k and constitute a plurality of electrode portions, and the tabs 1e which are respectively formed in a plurality of device regions 1k and constitute a plurality of chip mounting portions as shown in FIG. 4. Further, as shown in FIG. 5, the lead frame 1 includes the insulation tape (first film) 1f which constitutes the tape for tape molding which is laminated to a plurality of leads 1a and a plurality of tabs 1e.

That is, as mentioned previously, it is preferable to perform the lamination of the tape for tape molding with respect to the lead frame 1 prior to the die bonding step and the wire bonding step. Accordingly, in this embodiment, a case in which the insulation tape 1f which constitutes the tape for tape molding is preliminarily adhered to respective leads 1a and respective tabs 1e in respective device regions 1k is explained.

With respect to the insulation tape 1f which constitutes the tape for tape molding, it is preferable to use a tape having high heat resistance such as a polyimide tape, for example. In the example shown in FIG. 5, a sheet of insulation tape 1f is laminated to the lead frame 1 shown in FIG. 4.

Further, the respective leads 1a are connected to the inner frame portion 1j by way of the cut portions 1c shown in FIG. 1 respectively and each tab 1e is supported by the suspension leads 1g at four corner portions and the suspension leads 1g are connected to the inner frame portion 1j.

Further, as shown in FIG. 13 and 14, with respect to the lead frame 1 of this embodiment, the thickness of the cut portion 1c in each lead 1a is made smaller than the thickness of the external connection terminal portion 1b.

Thereafter, the die bonding shown in FIG. 6 is performed in which a plurality of semiconductor chips 2 each of which includes a plurality of pads 2a are fixed to the tabs 1e in a plurality of device regions 1k of the lead frame 1.

Here, the semiconductor chips 2 are fixed to the tabs 1e by way of the die bonding material 8 such as the silver paste shown in FIG. 1.

Since the tabs 1e are fixed to the insulation tape 1f, the die bonding step can be performed on the stable tabs 1e.

Thereafter, the wire bonding step is performed in which the respective pads 2a of a plurality of semiconductor chips 2 and the corresponding leads 1a which constitute a plurality of electrode portions in the lead frame 1 are electrically connected by way of a plurality of wires 4 as shown in FIG. 7.

Here, since the tab exposure structure in which the finish machining of the tabs 1e is not performed is adopted, heat generated by a heater of a wire bonder in the bonding stage is efficiently and uniformly transmitted to the semiconductor chips 2 by way of the insulation tape 1f and the tabs 1e so that the reliability of the wire bonding can be enhanced.

Further, since the tabs 1e are fixed to the insulation tape 1f, the wire bonding step can be performed on the stable tabs 1e.

Thereafter, the molding is performed so as to seal a plurality of semiconductor chips 2, a plurality of wires 4 and portions of the leads 1a and the tabs 1e of the lead frame 1 with the seal resin.

Here, as shown in FIG. 8, a plurality of semiconductor chips 2, a plurality of wires 4 and the portions of the leads 1a and the tabs 1e of the lead frame 1 are covered with one cavity 10c of an upper mold frame 10a, for example, of the mold frame 10 and the seal resin is filled in the cavity 1c so as to perform the block molding.

That is, after completion of the die bonding and the wire bonding, as shown in FIG. 8, the lead frame 1 is arranged on a molding surface of a lower mold frame 10b of the mold frame 10 such that the insulation tape 1f side of the lead frame 1 is disposed at the lower side and a plurality of semiconductor chips 2, a plurality of wires 4 and the leads 1a and the tabs 1e of the lead frame 1 are covered with one cavity 10c of the upper mold frame 10a and, thereafter, the block molding is performed.

Due to such a block molding, the resin sealing portion 3 in which a plurality of semiconductor chips 2 and a plurality of wires 4 are collectively sealed with resin.

For example, FIG. 16 and 17 show the back side (FIG. 16) and the front side (FIG. 17) of the post-molding structure of an example in which the block molding is performed by covering four device regions 1k with one cavity 10c, wherein four resin sealing portions 3 which collectively seal four device regions 1k are formed on the lead frame 1 shown in FIG. 4.

As shown in FIG. 9, after molding, the tape peeling-off step is performed so as to remove the insulation tape 1f laminated to a plurality of leads 1a and a plurality of tabs 1e so as to expose the surfaces (portions) of the external connection terminal portions 1b of a plurality of leads 1a.

Here, the back surfaces of the tabs 1e are also exposed.

Thereafter, as shown in FIG. 10, an exterior plating forming step is performed so as to apply a plating on the surfaces of the external connection terminal portions 1b and the surfaces of the tabs 1e of respective leads 1a which are exposed to the back surfaces 3a of the resin sealing portions 3.

Here, the exterior plating is constituted of a solder plating, for example, wherein the plating films 6 are formed on the surfaces of the external connection terminal portions 1b and the surfaces of the tabs 1e of respective leads 1a.

Here, the exterior plating may be formed of palladium (Pd) plating, for example. In this case, the palladium plating is applied in the lead frame stage which is performed prior to the package assembling.

Thereafter, the lead frame 1 and the resin sealing portion 3 are divided into the individual QFNs 5 corresponding to respective device regions 1k.

Here, the resin sealing portion 3 and the cut portions 1c of the lead frame 1 are cut together by dicing using the dicing blade 9 shown in FIG. 11 so as to divide them into individual QFNs 5 shown in FIG. 12.

In performing such a dicing, in the embodiment 1, as shown in FIG. 11, the dicing blade 9 is advanced from the front surface side of the resin sealing portion 3 which is collectively formed. Then, the dicing blade 9 is further advanced along dicing lines 1i shown in FIG. 17 so as to divide the resin sealing portions 3 into individual QFNs 5 by dicing for respective device regions 1k.

Here, with respect to the lead frame 1 of the embodiment 1, as shown in FIG. 13 and FIG. 14, the thickness of the cut portions 1c of the lead 1a is made thinner than the thickness of the external connection terminal portions 1b thus exhibiting the smaller cross-sectional area compared to the cross-sectional area of the external connection terminal portions 1b. Accordingly, as shown in FIG. 15, the lead sagging (lead burrs) 11 which are generated on the side surfaces 3b of the resin sealing portion 3 at the time of dividing the resin sealing portion 3 into individual QFNs 5 by dicing (at the time of cutting the leads) after molding can be reduced so that it is possible to prevent the lead sagging 11 from being projected to the back surface 3a side of the resin sealing portion 3.

Subsequently, a modification of the lead frame 1 of the embodiment 1 shown in FIG. 18 to FIG. 20 is explained hereinafter.

With respect to the lead frame 1 shown in FIG. 18 and FIG. 19, in making the cross-sectional area of a cut portion 1c of a lead 1a on a plane parallel to a side surface 3b of a resin sealing portion 3 smaller than a cross-sectional area of an external connection terminal portion 1b, a width of each cut portion 1c (third portion) is set smaller than a width of the external connection terminal portion 1b (second portion) with respect to the arrangement direction of a plurality of leads 1a.

That is, with respect to a plurality of leads 1a, the width of the cut portion 1c of each lead 1a is made narrower than the width of the external connection terminal portion 1b of the lead 1a. Due to such a constitution, each distance defined between a plurality of cut portions 1c which are exposed to the side surfaces 3b of the resin sealing portion 3 can be set larger than the distance between the external connection terminal portions 1b.

Accordingly, as shown in FIG. 20, the distance between the read sagging 11 and the cut portion 1c of the neighboring lead 1a can be increased so that the short-circuiting between the lead cut portions 1c due to the lead sagging 11 can be prevented.

In the structure which narrows the width of the cut portion 1c as shown in FIG. 18 and FIG. 19, to prevent the deterioration of the flatness of the lead 1a while ensuring the strength of the cut portion 1c, the thickness of the cut portion 1c of the lead 1a can be made equal to or more than the thickness of the external connection portion 1b as shown in FIG. 20. Further, the cut portion 1c may have the thickness which is equal to or less than the thickness of the external connection terminal portion 1b when the cut portion 1c can ensure the sufficient strength even when the cut portion 1c is thin.

(Embodiment 2)

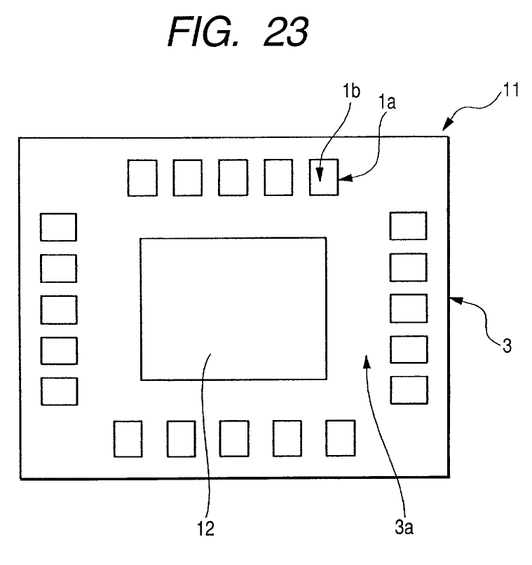

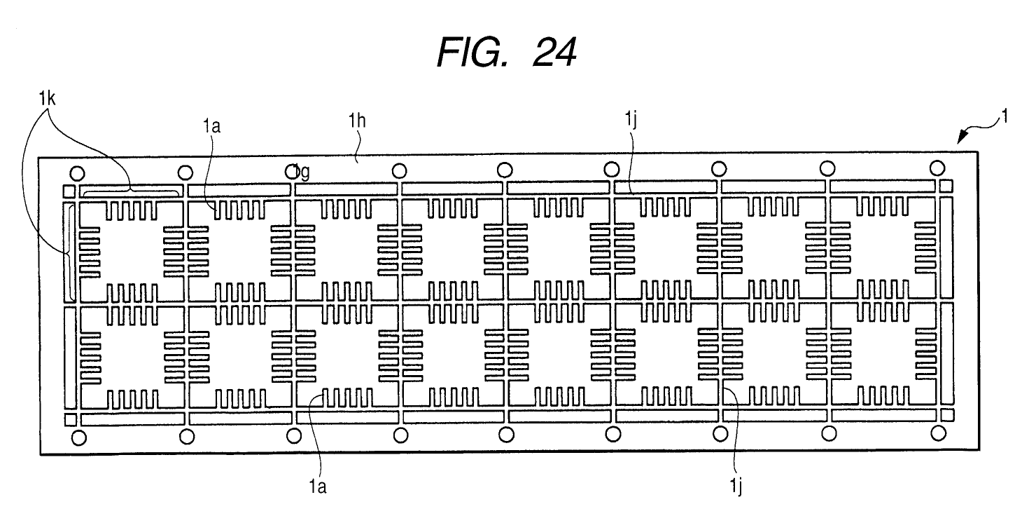

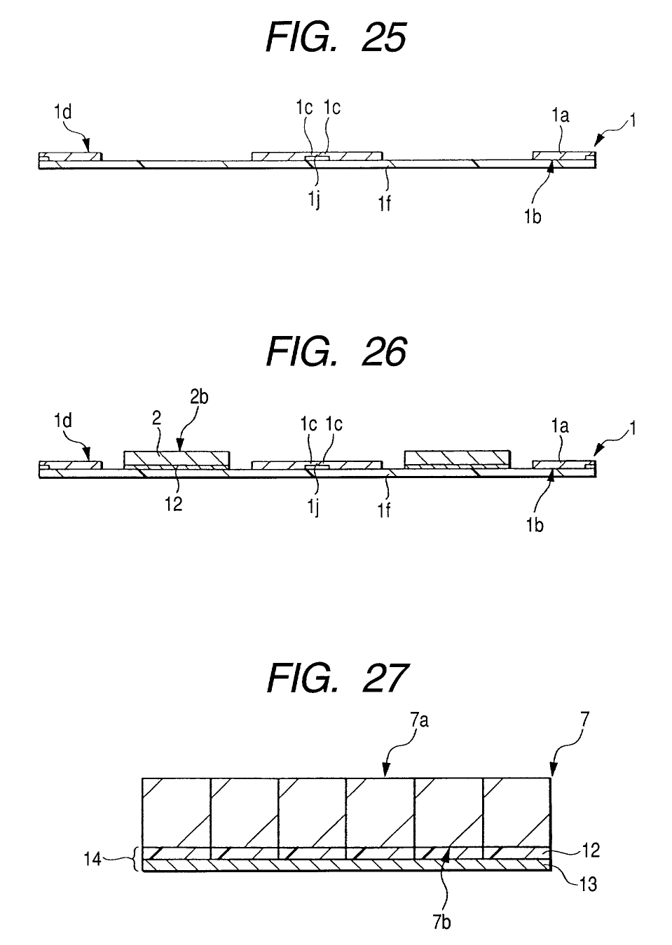

In the drawings, FIG. 21 is a cross-sectional view showing one example of the structure of a semiconductor device (QFN) of the second embodiment of the present invention, FIG. 22 is a side view showing the structure of the semiconductor device shown in FIG. 21, FIG. 23 is a bottom plan view showing the structure of the semiconductor device shown in FIG. 21, FIG. 24 is a plan view showing one example of the structure of a lead frame used in the assembling of the semiconductor device shown in FIG. 21, FIG. 25 is a cross-sectional view showing one example of the structure of the lead frame after a tape is laminated to the lead frame shown in FIG. 24, FIG. 26 is a cross-sectional view showing one example of a structure in a semiconductor chip fixed state in the assembling of the semiconductor device shown in FIG. 21, and FIG. 27 is a cross-sectional view showing one example of a semiconductor wafer structure for obtaining fixing semiconductor chips in the assembling of the semiconductor device shown in FIG. 21.

In the QFN 11 of this embodiment 2 shown in FIG. 21 to FIG. 23,. chip fixing tapes (second films) 12 formed of an insulation body are used in place of the tabs 1e as chip mounting portions.

That is, as shown in FIG. 21, a semiconductor chip 2 is fixed to the chip fixing tape 12. Here, the chip fixing tape 12 is constituted of an insulation tape member such as a polyimide tape provided with an adhesive layer, for example.

Accordingly, the QFN 11 is not provided with the tabs 1e and the suspension leads 1g which support the tab 1e as shown in FIG. 3 and hence, as shown in FIG. 23, a portion of an external connection terminal portion 1b (exposed surface) of each lead 1a and the chip fixing tape 12 are exposed to the back surface 3a of the resin sealing portion 3.

Due to such a constitution, with respect to a mounting substrate 15 on which the QFN 11 is mounted, as shown in FIG. 35, it is also possible to form an uppermost-layer wiring 15a (wiring constituting the same layer as a mounting land) on a region of the QFN 11 below the chip fixing tape 12 so that the mountability can be enhanced.

That is, with respect to the QFN 5 which has been explained in conjunction with the embodiment 1, when the uppermost layer wiring 15a (particularly, signal line) is arranged below the tab 1e of the mounting substrate 15, the semiconductor chip 2 picks up noises from the wiring by way of the tab 1e and hence, it is difficult to arrange the uppermost layer wiring 15a of the mounting substrate 15 below the tab 1e.

This tendency becomes more apparent when the surface of the semiconductor chip 2 opposite to a main surface 2b of the semiconductor chip 2 and the tab 1e are electrically connected to each other.

On the other hand, according to the QFN 11 of the embodiment 2, the insulative chip fixing tape 12 is arranged at the back surface of the chip and hence, the insulation of the back surface of the chip can be ensured so that the influence of the noises from the uppermost layer wiring 15a of the mounting substrate 15 can be reduced. Accordingly, as shown in FIG. 35, it is possible to arrange the uppermost layer wiring 15a such as the signal wiring at the mounting substrate 15 even right below the semiconductor chip 2.

As a result, the wiring density of the mounting substrate 15 can be enhanced so that the mounting substrate 15 can be miniaturized. Here, an inner wiring 15b is formed in the mounting substrate 15 and the inner wiring 15b is connected to the uppermost layer wiring 15a by way of a via hole wiring 15c. Further, a lead 1a of the QFN 11 is connected to the uppermost layer wiring 15a by way of a solder fillet 16. Still further, a portion of the uppermost layer wiring 15a is covered with a solder resist film 15d.

To assemble the QFN 11, first of all, a tabless lead frame 1 shown in FIG. 25 which is formed by laminating an insulation tape if which constitutes a first film to the lead frame 1 is prepared.

On the other hand, with respect to the semiconductor chip 2, as shown in FIG. 27, a semiconductor wafer 7 having a back surface 7b thereof to which a chip fixing tape 12 is preliminarily laminated is prepared and, thereafter, the semiconductor wafer 7 is divided into individual QFNs by dicing so as to prepare the semiconductor chips 2 which laminates the chip fixing tapes 12 to the back surfaces 7b thereof. The semiconductor chips 2 are fixed to the insulation tape 1f by way of the chip fixing tapes 12.

That is, for example, a two-layered dicing tape 14 which is constituted of the chip fixing tape 12 having an adhesive layer and an ultraviolet ray irradiation type tape 13 is laminated to back surface 7b of the semiconductor wafer 7. Then, the semiconductor wafer 7 and the chip fixing tape 12 are cut from the main surface 7a side in the wafer state and, at the same time, the dicing tape 14 is half-diced so as to divide the semiconductor wafer into individual semiconductor chips 2 while preventing the scattering thereof.

Thereafter, ultraviolet rays are irradiated to the ultraviolet-ray irradiation type tape 13 of the dicing tape 14 so as to weaken the adhesive force of the ultraviolet-ray irradiation type tape 13.

Subsequently, the semiconductor chips 2 are peeled off from the ultraviolet-ray irradiation type tape 13 and are divided into individual semiconductor chips, as shown in FIG. 26, and the die bonding is performed so as to fix the individual semiconductor chips 2 to the insulation tape 1f of the tabless lead frame 1 by way of the chip fixing tape 12.

Thereafter, in the same manner as the assembling of the QFN 5 of the embodiment 1, the wire bonding, the block molding, the peeling-off of the insulation tape 1f and the separation into individual packages by dicing are sequentially performed so as to manufacture the QFN 11 shown in FIG. 21 to FIG. 23.

Here, in the assembling of the QFN 11 of the embodiment 2, the chip fixing tapes 12 which are fixed to respective device regions 1k are exposed by peeling off the insulation tape 1f.

In the QFN 11 of this embodiment 2, since the semiconductor chips 2 can be supported using the chip fixing tapes 12 which are thinner than the tabs 1e shown in FIG. 1, the QFN 11 can be made further thinner and, at the same time, the insulation below the chips can be reliably ensured by interposing the insulative chip fixing tapes 12 below the chips.

Considering that the insulation tape 1f is peeled off after molding, it is preferable to adopt the chip fixing tape 12 which exhibits high peelability. It is also possible to use a tape member whose adhesive strength can be weakened by the irradiation of ultraviolet rays in the same manner as ultraviolet ray irradiation type tape 13.

Although the invention which has been made by inventors has been specifically explained in conjunction with the embodiments of the present invention, the present invention is not limited to the above-mentioned embodiments of the present invention and it is needless to say that various modifications are conceivable without departing from the gist of the present invention.

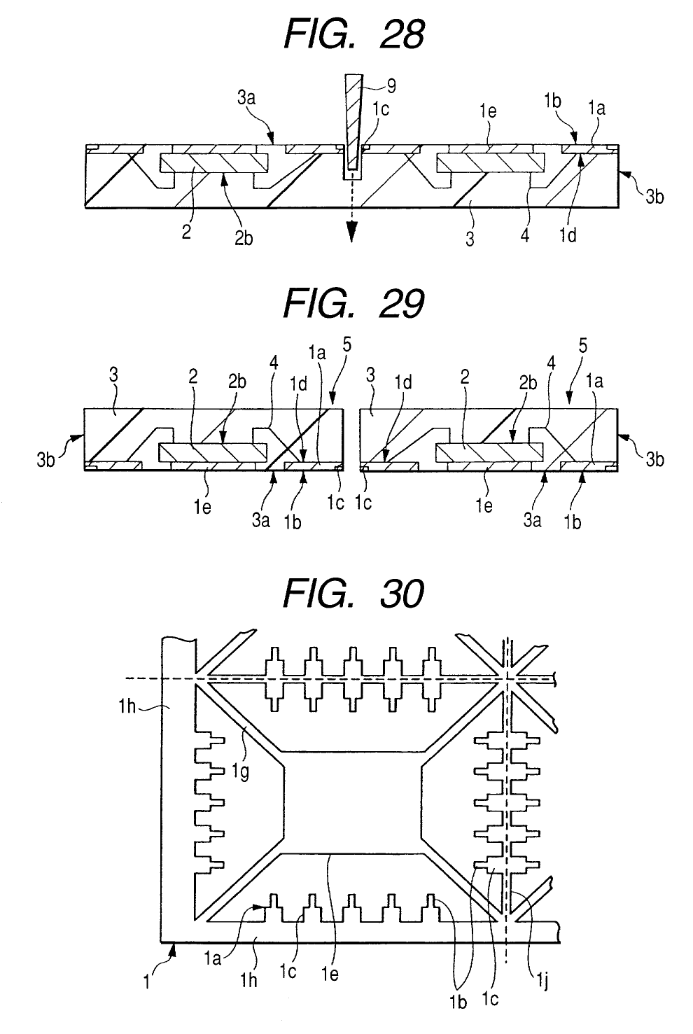

For example, in the embodiment 1, in performing the dicing after the block molding, the advancing direction of the dicing blade 9 is set to a direction from the surface side of the resin sealing portion 3. However, as in the case of another embodiment shown in FIG. 28, the dicing blade 9 may be advanced from the back surface 3a side of the resin sealing portion 3 so as to divide the lead frame 1 into individual QFNs 5 as shown in FIG. 29.

In this case, the dicing blade 9 is made to travel along the dicing line 1i on the back surface 3a side of the resin sealing portion 3 shown in FIG. 16 so as to divide the lead frame 1 into individual QFNs 5 as shown in FIG. 16.

By advancing the dicing blade 9 from the back surface 3a side of the resin sealing portion 3 as shown in FIG. 28, the alignment prior to the dicing or during the dicing can be performed by detecting the external connection terminal portion 1b of the lead 1a exposed to the back surface 3a of the resin sealing portion 3 and further by utilizing a pattern of the external connection terminal portion 1b (here, however, the pattern of the lead 1a including the resin pattern on the back surface 3a of the resin sealing portion 3 which is in an complementary relationship with the pattern of the lead 1a) Accordingly, it is possible to prevent the rupture of the lead 1a which may occur due to the displacement of alignment at the time of performing the dicing. Accordingly, with respect to the dicing which is performed after the alignment is performed based on the pattern of the lead 1a, it is preferable to advance the dicing blade 9 from the lead 1a side.

Further, with respect to the structure which makes the cut portion 1c of the lead 1a in the embodiment 1 and the embodiment 2 thin, to prevent the bending of the lead 1a in the lateral direction while ensuring the strength of the cut portion 1c, the lead width of the cut portion 1c may be set to a value equal to the lead width of the external connection terminal portion 1b. Alternatively, as in the case of the lead 1a of another embodiment shown in FIG. 30, the lead width of the cut portion 1c may be set to a value larger than the width of the external connection terminal portion 1b.

Further, when the cut portion 1c of the lead 1a is narrow in width but still can ensure the sufficient strength thereof, the width of the cut portion 1c of the lead 1a may be set to a value equal to or less than the width of the external connection terminal portion 1b.

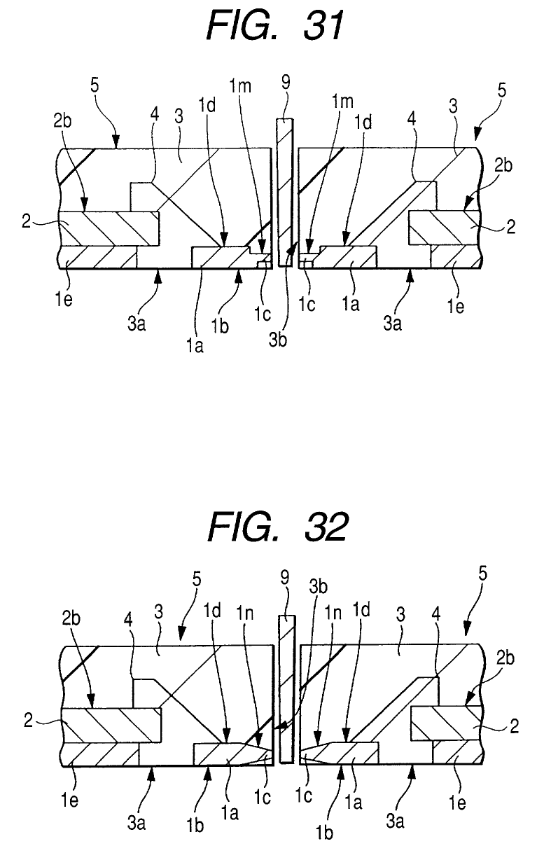

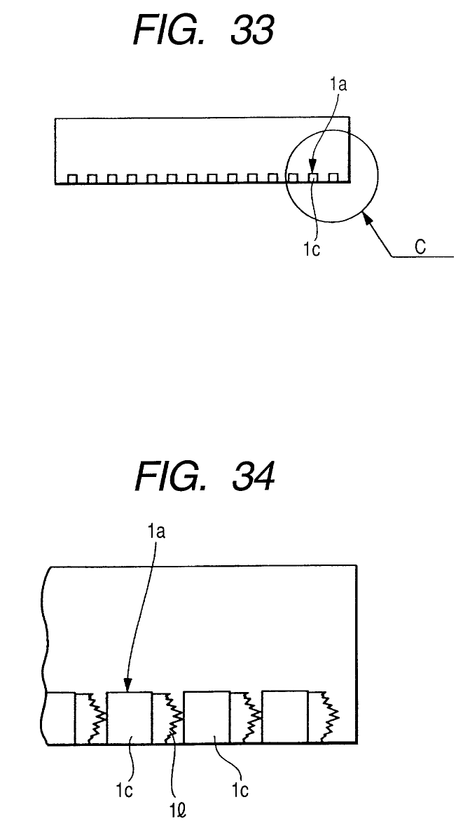

Still further, to make the cut portion 1c of the lead 1a thinner than the external connection terminal portion 1b, as in the case of another embodiments shown in FIG. 31 and FIG. 32, besides the mounting surface side of the cut portion 1c, the upper side of the cut portion 1c is also recessed to make the cut portion 1c thin.

Here, with respect to the lead 1a shown in FIG. 31, an upper recessed portion 1m is formed in the cut portion 1c. Due to such a constitution, it is possible to make the resin sealing portion 3 overhang at the upper side of the cut portion 1c so that the adhesiveness between the resin sealing portion 3 and the lead 1a can be enhanced and, at the same time, a peel-off stress between the resin sealing portion 3 and the lead 1a which is generated when the lead is cut can be reduced.

Further, with respect to the lead 1a shown in FIG. 32, an upper inclined recessed portion 1n is formed in the cut portion 1c. Due to such a constitution, it is also possible to reduce the peel-off stress which is generated between the resin sealing portion 3 and the lead 1a at the time of cutting the lead 1a.

To briefly recapitulate the advantageous effects obtained by the typical inventions out of the inventions disclosed in this application, they are as follows.

By making the cross-sectional area of the cut portion of the lead on the plane parallel to the side surfaces of the resin sealing portion smaller than the cross-sectional area of the external connection terminal portion, the lead sagging which is generated due to the dicing after the block molding can be reduced.

What is claimed is:

1. A semiconductor device comprising:
a resin sealing portion which has a plurality of side surfaces and a mounting surface formed between the plurality of side surfaces;
a semiconductor chip which is sealed by the resin sealing portion and includes a plurality of electrodes;
a plurality of leads which are formed of conductor, each lead having a first portion sealed by the resin sealing portion, a second portion exposed to the mounting surface and third portions exposed to the side surfaces;
a plurality of wires which are sealed by the resin sealing portion, the wires electrically connecting the plurality of leads with a plurality of electrodes of the semiconductor chip, respectively,
wherein a plating film is formed on a surface of the second portion of the lead and the plating film is not formed on a surface of the third portions of the lead.

2. A semiconductor device according to claim 1, wherein the leads are constituted of copper or a copper alloy and the plating film has a low hardness compared with a hardness of the copper or the copper alloy which constitutes the lead.

3. A semiconductor device according to claim 1, wherein on a plane parallel to side surfaces to which the third portions are exposed, a cross-sectional area of the third portion is set smaller than a cross-sectional area of the second portion.

4. A semiconductor device according to claim 1, wherein the third portiona are covered with the resin sealing portion on the mounting surface.

5. A semiconductor device comprising:
a resin sealing portion which has a plurality of side surfaces and a mounting surface formed between the plurality of side surfaces;
a semiconductor chip which is sealed by the resin sealing portion and includes a plurality of electrodes;
a plurality of leads which are formed of conductor, each lead having a first portion sealed by the resin sealing portion, a second portion exposed to the mounting surface and third portions exposed to the side surfaces;
a plurality of wires which are sealed by the resin sealing portion, the wires electrically connecting the plurality of leads with a plurality of electrodes of the semiconductor chip, respectively,
wherein, in a plurality of leads, a distance between the third portions is set larger than a distance between the second portions.

6. A semiconductor device according to claim 5, wherein, with respect to an arrangement direction of a plurality of leads, a width of the third portion is set smaller than a width of the second portion.

7. A semiconductor device comprising:
a resin sealing portion which has a plurality of side surfaces and a mounting surface formed between the plurality of side surfaces;
a semiconductor chip which is sealed by the resin sealing portion and includes a plurality of electrodes;
a plurality of leads which are formed of conductor, each lead having a first portion sealed by the resin sealing portion, a second portion exposed to the mounting surface and third portions exposed to the side surfaces;
a plurality of wires which are sealed by the resin sealing portion, the wires electrically connecting the plurality of leads with a plurality of electrodes of the semiconductor chip, respectively,
wherein lead burrs are formed on surfaces of the third portions of the leads and are retracted from exposed surfaces of the second portions of the leads.

8. A semiconductor device comprising:
a resin sealing portion which has a plurality of side surfaces and a mounting surface formed between a plurality of side surfaces;
a semiconductor chip which is sealed by the resin sealing portion and includes a plurality of electrodes;
a plurality of leads which are formed of conductor, each lead having a first portion sealed by the resin sealing portion, a second portion exposed to the mounting surface and third portions exposed to the side surfaces;
a plurality of wires which are sealed by the resin sealing portion, the wires electrically connecting the plurality of leads with a plurality of electrodes of the semiconductor chip, respectively; and
a chip mounting portion which is formed of an insulating body and exposed to mounting surfaces of the resin sealing portions.

9. A manufacturing method of a semiconductor device comprising the steps of:
(a) preparing a lead frame having a first frame portion, a second frame portion which is formed inside the first frame portion, a plurality of device regions which are formed inside the second frame portion, a plurality of electrode portions which are respectively formed on the plurality of device regions, and first films which are laminated to a plurality of electrode portions;
(b) fixedly mounting a plurality of semiconductor chips each of which includes a plurality of electrodes on the plurality of device regions of the lead frame;
(c) respectively connecting the plurality of electrodes of the plurality of semiconductor chips with the plurality of electrode portions of the lead frame by means of a plurality of wires;
(d) sealing the plurality of semiconductor chips, the plurality of wires and a portion of the lead frame with sealing resin;
(e) removing the first films adhered to the plurality of electrode portions after the sealing step and exposing at least a portion of the plurality of electrode portions; and
(f) separating the lead frame and the sealing resin portion corresponding to every device region after the sealing step.

10. A manufacturing method of a semiconductor device according to claim 9, wherein after the step (e) and before the step (f), a plating is applied to the portions of the electrode portions which are exposed in the step (e).

11. A manufacturing method of a semiconductor device according to claim 9, wherein the lead frame which is prepared in the step (a) includes chip mounting portions laminated to the first films at the plurality of respective device regions, and in the step (b), the plurality of semiconductor chips are respectively fixed to the chip mounting portions.

12. A manufacturing method of a semiconductor device according to claim 9, wherein in the step (b), the plurality of semiconductor chips are respectively fixed to the first films by way of second films which constitute chip mounting portions formed of an insulating body.

13. A manufacturing method of a semiconductor device according to claim 12, wherein in the step (e), at least a portion of the second films are exposed by removing the first films.

14. A manufacturing method of a semiconductor device according to claim 9, wherein a polyimide tape is used as the first films.

15. A manufacturing method of a semiconductor device according to claim 9, wherein in dividing the resin sealing portion into individual pieces for every device region in the step (f), an alignment is performed by detecting the second portions of the plurality of leads which are exposed to mounting surfaces of the resin sealing portion, and the resin sealing portion is divided into the individual pieces by advancing a dicing blade from the mounting surface side of the resin sealing portion.

16. A manufacturing method of a semiconductor device according to claim 12, wherein in fixing the semiconductor chips by way of the second films, semiconductor chips in which the second films are adhered to back surfaces are prepared by dividing a semiconductor wafer in which the second films are preliminarily adhered to a back surface into individual pieces by dicing, and the semiconductor chips are fixed to the first films by way of the second films.
